(19) United States
(12) Patent Application Publication
(10) Pub. No.: US 2009/0134887 A1
(43) Pub. Date: May 28, 2009

(54) CONTACT SENSOR

(76) Inventors: Wei-Chih Hu, Chung Li (TW); Liang-Yu Shyu, Chung Li (TW); Pai-Yuan Tsai, Taiping (TW); Hsin-Chang Chen, Banciao City (TW)

Correspondence Address: SINORICA, LLC, 528 FALLSGROVE DRIVE, ROCKVILLE, MD, 20850, US

(21) Appl. No.: 12/101,748

(22) Filed: Apr. 11, 2008

(30) Foreign Application Priority Data
Nov. 22, 2007 (TW) 096144289

(51) Int. Cl. G01R 27/02

(52) U.S. Cl. 324/692

(57) ABSTRACT

A contact sensor is disclosed. The contact sensor includes a main body and at least one conductor. At least one end of the conductor is disposed on the main body and a contact surface is on one side of the conductor for contact the body surface. The surface of the conductor is in the shape of arc. By the contact surface of the conductor, the contact sensor contacts the human body easily without tangling hair. Moreover, there is not need for the present invention to apply any conductive gel on the body surface so that the measurement of physiological signals is easily and conveniently.

### BACKGROUND OF THE INVENTION

The present invention relates to a sensor, especially to a contact sensor.

There are a plurality of physiological signals in human bodies such as Electrocardiogram (ECG) signals, electroencephalogram (EEG) signals and neural signals. Generally, the ways of measuring signals for medical purposes are according to signal strength. For example, conventional electroencephalogram (EEG) are measured by a plurality of wet electrodes. During the measuring process, apply EEG gel on patients' scalps. Thus when a person is monitored by electroencephalogram (EEG), the medical technician firstly apply some conductive gel on certain positions of the head that is attached with the wet electrodes so that the electrodes detect electrical activities completely through the conductive gel. After finishing detection, the person needs to wash his/her hair for removing the conductive gel. This causes inconvenience to patients. On daily life, the measurement by wet electrodes is not so easy and convenient. Users need to wash the skin being applied with conductive gel after each time of measurement. On the other hand, although invasive electrodes get physiological signals with better quality, the use of invasive instruments has been the focus of heavy research due to complications of invasive processes such as infection. For example, to get EEG signals, the invasive EEG recordings are made with electrodes that have been surgical implanted on the surface or within the depth of the brain so that incomplete disinfection and sterilization may jeopardize patients' safety. Due to considerations of safety and acceptance, most of patients will choose not to use the invasive recordings of ECG or EEG.

Refer to FIG. 1, a conventional contact sensor is revealed. The contact sensor 10 consists of a main body 12 and a plurality of needle-shaped conductors 14 disposed on the main body 12. By means of these needle-shaped conductors 14, the conventional contact sensor 10 contacts the human skin so as to measure physiological signals in human bodies such as Electrocardiogram (ECG) signals, and electroencephalogram (EEG) signals. However, these needle-shaped conductors 14 cause patients uncomfortable feelings. Moreover, the needle-shaped conductors 14 may make users get tangles in body hair. Although people avoid inconvenience of removing conductive gel, here comes another problem—it creates tangles in hair.

Thus there is a need to provide a novel contact sensor not only overcomes shortcomings of conventional sensors with wet electrodes but also ward off uncomfortable feelings while getting higher-quality physiological signals.

### SUMMARY OF THE INVENTION

Therefore it is a primary object of the present invention to provide a contact sensor that attaches on surface of human bodies for measurement of physiological signals without applying conductive gel on the surface of human bodies.

In order to achieve above object, the present invention provide a contact sensor. The contact sensor includes a main body and at least one conductor. The conductor is disposed on the main body and is in the shape of arc with two ends coupled to the main body. By the conductor, the contact sensor contacts the human body for measuring physiological signals. Moreover, there is not need for the present invention to apply any conductive gel on the body surface. Therefore, the contact sensor of the present invention improves patient's acceptance of the device and there is no conductive gel residue after the measurement. Moreover, the contact sensor further includes a processing circuit coupled to the conductor for processing physiological signals detected by the conductor of the contact sensor.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a schematic drawing of a conventional contact sensor;

FIG. 2 is a schematic drawing showing an embodiment of the present invention;

FIG. 3 is a block diagram showing circuitry of an embodiment according to the present invention;

FIG. 4 is a schematic drawing showing contact sensors of the present invention disposed on a strap;

FIG. 5 is a schematic drawing of another embodiment of the present invention showing a strap on the head;

FIG. 6 is a schematic drawing of another embodiment according to the present invention;

FIG. 7 is a schematic drawing of a further embodiment according to the present invention.

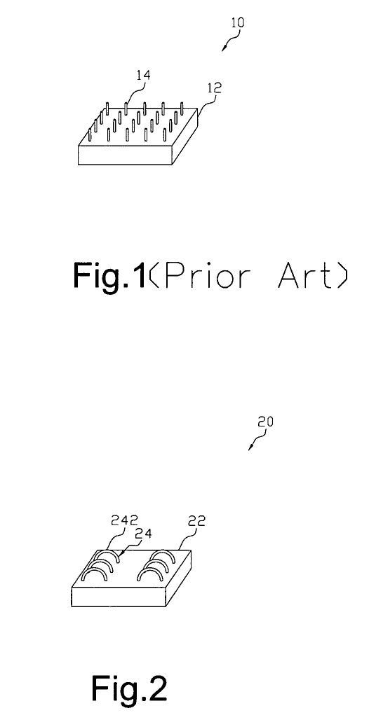

### DETAILED DESCRIPTION OF THE PREFERRED EMBODIMENT

Refer to FIG. 2, a contact sensor 20 according to the present invention includes a main body 22 and at least one conductor 24 disposed on the main body 22. In this embodiment, a plurality of conductors 24 is arranged on the main body 22. One side of the conductor 24 is a contact surface 242 with the shape of arc and two ends of the conductor 24 are coupled to the main body 22. By the contact surface 242, the contact sensor 20 attaches the human body for measuring physiological signals. The design of the conductor 24 is for providing users feelings of comfort after being attached with the contact sensor 20. Moreover, the conductor 24 needs to pass through body hairs on the surface so as to contact the skin on surface of the body. For example, for EEG signal recording, the conductor 24 passes through thick hair to contact the scalp for measurement of the EEG signals. Because the shape of the conductor 24 is arc so that the users attached with the contact sensor 20 won't feel sting. Furthermore, the contact area of the conductor 24 to the scalp is larger than a conventional device so that the contact sensor 20 of the present invention has better effects on signal acquisition.

Moreover, the conductor 24 of the present invention is made from silver, silver chloride, or combinations of them. When the conductor 24 is made from silver chloride, it is electroplated by an electroplating device. By a silver wire coupled to a positive electrode of a power source and a silver piece is coupled to a negative electrode of the power sources while both the silver wire and the silver piece are set in nitric acid solution, the conductor 24 including silver chloride is prepared.

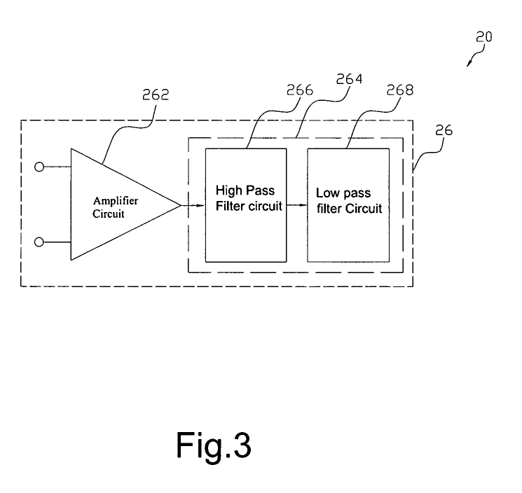

Refer to FIG. 3, a block diagram of circuitry according to an embodiment of the present invention is revealed. The contact sensor 20 of the present invention further includes a processing circuit 26 having an amplifier circuit 262 and a filter circuit 264. The amplifier circuit 262 is coupled to the conductor 24 of the contact sensor 20 and the filter circuit 264 is coupled to the amplifier circuit 262. The amplifier circuit 262 of the present invention is an instrumentation amplifier circuit. Moreover, the preferred gain of the amplifier circuit 262 is 101. The filter circuit 264 of the present invention is a band pass filter circuit having a high pass filter circuit 266 and a low pass filter circuit 268. The high pass filter circuit 266 is coupled to the amplifier circuit 262 while the low pass filter circuit 268 is coupled to the high pass filter circuit 266. Furthermore, the gain of the high pass filter circuit 266 as well as the low pass filter circuit 268 is respectively 51 and 2.

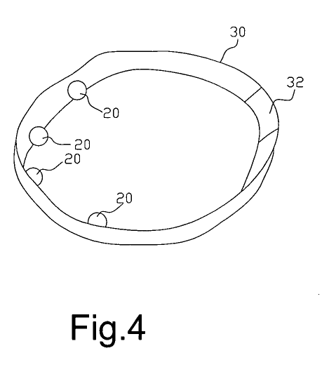

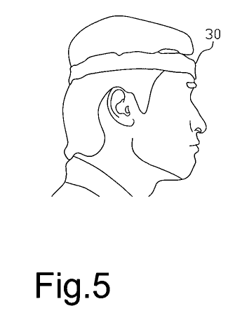

Refer to FIG. 4, at least one contact sensor 20 is disposed on a strap 30. According to users' requirements, a plurality of contact sensors 20 is arranged on the strap 30. The strap 30 is arranged with an elastic ribbon 32 so that by the strap 30 together with the elastic ribbon 32, the contact sensors 20 are attached on the head, as shown in FIG. 5. Moreover, a touch fastener is used to fix the contact sensor 20 on the strap 30 so as to attach the patient's head.

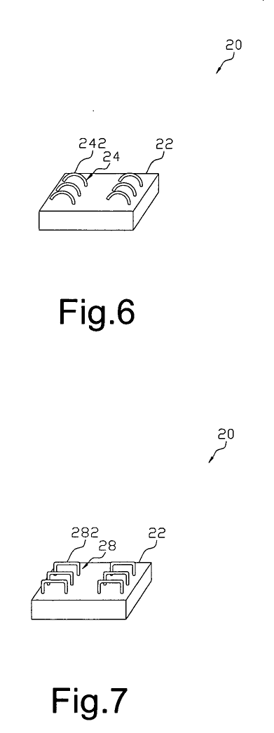

Refer to FIG. 6, another embodiment is disclosed. The difference between this embodiment and the embodiment in FIG. 2 is in that the conductor 24 of the embodiment in FIG. 2 has two ends coupled to the main body 22 while the conductor 24 of the embodiment in FIG. 2 has only one end coupled to the main body 22 while the other end of the conductor is not. In this embodiment, a contact surface 242 on one end of the conductor 24 contacts the body surface for physiological signal detection. Refer to FIG. 7, a further embodiment is revealed. The difference between this embodiment and the embodiment in FIG. 6 is in that the conductor 28 is [symbol] -shaped and two ends of the conductor 28 are coupled to the main body 22 while one side of the conductor 28 is a contact surface 282 for contacting the body surface to record physiological signals. Furthermore, the conductor 28 may only has one end coupled to the main body 22 wile the other end thereof is not.

In summary, a contact sensor according to the present invention consists of a main body and at least one conductor. The conductor is disposed on the main body and in arc shape. By the arc conductor, the contact sensor contacts the body surface without tangling. Moreover, there is no need to apply conductive gel for measurement of physiological signals under the body surface. This is quite convenient for users that often receive physiological signal recordings. Furthermore, the contact sensor further includes a front end circuit composed of an amplifier circuit and a band pass filter circuit. The band pass filter circuit consists of a high pass filter circuit and a low pass filter circuit.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalents.

What is claimed is:

1. A contact sensor comprising:
a main body; and
at least one conductor in the shape of arc and with two ends thereof coupled to the main body.

2. The device as claimed in claim 1, wherein the contact sensor further comprising:
a processing circuit coupled to the conductor.

3. The device as claimed in claim 2, wherein the processing circuit comprising:
an amplifier circuit coupled to the conductor; and
a filter circuit coupled to the amplifier circuit.

4. The device as claimed in claim 3, wherein the amplifier circuit is an instrumentation amplifier circuit.

5. The device as claimed in claim 3, wherein the filter circuit is a band pass filter circuit.

6. The device as claimed in claim 5, wherein the band pass filter circuit comprising:
a high pass filter circuit coupled to the amplifier circuit; and
a low pass filter circuit coupled to the high pass filter circuit.

7. The device as claimed in claim 1, wherein the conductor is made from silver, silver chloride or combinations of them.

8. A contact sensor comprising:
a main body; and
at least one conductor with a contact surface on one side thereof and one end of the conductor is coupled to the main body.

9. The device as claimed in claim 8, wherein the contact is a curved surface.

10. The device as claimed in claim 8, wherein the contact sensor further comprising:
a processing circuit coupled to the conductor.

11. The device as claimed in claim 10, wherein the processing circuit comprising:
an amplifier circuit coupled to the conductor; and
a filter circuit coupled to the amplifier circuit.

12. The device as claimed in claim 11, wherein the amplifier circuit is an instrumentation amplifier circuit.

13. The device as claimed in claim 11, wherein the filter circuit is a band pass filter circuit.

14. The device as claimed in claim 13, wherein the band pass filter circuit comprising:
a high pass filter circuit coupled to the amplifier circuit; and
a low pass filter circuit coupled to the high pass filter circuit.

15. The device as claimed in claim 8, wherein the conductor is made from silver, silver chloride or combinations of them.
